(19) United States
(12) Patent Application Publication
(10) Pub. No.: US 2004/0251780 A1
(43) Pub. Date: Dec. 16, 2004

(54) Advanced ceramics in ultrasonic transducerized devices

(76) Inventor: J. Michael Goodson, Skillman, NJ (US)

Correspondence Address: STALLMAN & POLLOCK LLP, SUITE 2200, 353 SACRAMENTO STREET, SAN FRANCISCO, CA, 94111, US

(21) Appl. No.: 10/840,919

(22) Filed: May 7, 2004

Related U.S. Application Data
(60) Provisional application No. 60/469,163, filed on May 9, 2003.

(51) Int. Cl. H01L 41/18

(52) U.S. Cl. 310/323.18

(57) ABSTRACT

Ultrasonic processes and systems demonstrate enhanced performance when various elements and/or components of an ultrasonic device are formed from Advanced Ceramic materials. An ultrasonic tool formed of an Advanced Ceramic can vibrate at the same frequency as the ultrasonic transducer(s) used to supply the ultrasonic energy, such that the tool functions as a single, fully-integrated transducerized entity. Piezo ceramics such as PZTs can be used to provide the ultrasonic energy, and can be directly attached to the tool, individually or in stacks. The resonance characteristics of the ultrasonic tool can be further enhanced by setting a thickness of the tool to an optimum thickness, whereby the tool can resonate uniformly upon excitation. In addition to providing enhanced performance, Advanced Ceramic tools do not demonstration the erosion or cavitation found in other existing tools.

### CLAIM OF PRIORITY

This patent application claims priority to U.S. provisional patent application No. 60/469,163, entitled “ADVANCED CERAMICS AS AN ULTRASONIC RESONATING TANK,” filed May 9, 2003, which is hereby incorporated herein by reference.

### TECHNICAL FIELD OF THE INVENTION

The present invention relates to devices and applications using transducers which generate and transmit energy in the ultrasonic region, such as may be useful for ultrasonic cleaning, ultrasonic wire bonding, and ultrasonic medical device applications.

### BACKGROUND

Ultrasonic devices can be used for generating and transmitting wave energy of a predetermined frequency to a material. An ultrasonic device typically includes a power supply that converts line power to an ultrasonic frequency. An ultrasonic transducer, which can contain a number of piezoelectric elements, can use the ultrasonic frequency signal to generate a mechanical vibration at that frequency. Ultrasonic transducers often have one or more crystals sandwiched between a head mass (or front driver) and a tail mass (or rear driver). Ultrasonic devices of this type are used, for example, in ultrasonic cleaning equipment as described in U.S. Pat. No. 3,575,383, entitled “ULTRASONIC CLEANING SYSTEM, APPARATUS AND METHOD THEREFOR.” In an existing ultrasonic cleaning and/or liquid processing system 100, such as is shown in FIG. 1, the wall(s) and/or bottom surface of a tank 102 capable of holding the part(s) to be cleaned can be used as a diaphragm, such that when a transducer bonded to the tank wall vibrates at a resonant frequency, the diaphragm begins to vibrate whereby waves of energy are transmitted to the fluid in the tank to create a cavitation processes. As seen in the Figure, the transducer includes at least one PZT layer 106, a pair of electrodes 104, a head mass 108 and a tail mass 110. Here, the head mass 108 is bonded to the tank 102 at a number of contact positions, creating a number of hot spots 112 in the tank, as discussed below. The high-frequency waves of energy remove contaminants or other materials from parts (not shown) immersed in the fluid without damaging the parts. The parts to be cleaned can be immersed in any of a variety of cleaning agents or fluids as known in the industry, the choice of which can depend at least in part on the material of the part(s) being cleaned. In the cavitation process, small bubbles form in the immersion fluid to the waves of energy generated in the fluid by the transducer. The bubbles increase in size until implosion, at which time energy stored inside each bubble is released. The implosion changes the bubble into a burst of energy that can propagate towards a nearby surface, which then frees contaminants from the parts. The resonant frequency of the transducer determines the size of the bubbles, and therefore the amount of energy released by each bubble.

An ultrasonic cleaning system can utilize a bank of ultrasonic transducers bonded to the tank walls. Typical piezoelectric transducers include a piezoelectric crystal sandwiched between two metal strips, such that when voltage is applied across the strips a displacement is created in the crystal as known in the art. When these transducers are bonded to a tank, the displacement causes a movement of the diaphragm. The energy will be absorbed by parts immersed in the fluid, such that there must be a substantial amount of energy in the tank to support cavitation and obtain acceptable cleaning performance. Typically, the tank walls must be relatively thin in order to obtain acceptable energy transference, which can have the problem of oscillating at the upper harmonic frequencies and creating smaller implosions. Further, cavitation erosion can occur that can wear through a thin diaphragm, causing damage to the transducers and rendering the device inoperable.

Ultrasonics are also used in many other applications. FIG. 2 shows an example of an existing ultrasonic device 200, which consists of a tail mass 204, stack of ring PZTs 208, a pair of electrodes 206, and a head mass 210. This device also includes a bolt 202 that can be bonded or threadably attached to the head mass 210 through the PZT stack, as known in the art. This exemplary ultrasonic device also includes an extended tool portion 212, typically formed of stainless steel or titanium, that is bonded to the head mass 210. This extended portion 212 can have a shape and size that depends on the application, such as a horn for wire bonding or a blade for ultrasonic cutting. In one example, wires can be bonded to devices such as power transistors by applying a low-amplitude but ultrasonic frequency force directly to the part being bonded. A horn is typically used to deliver the vibration energy, which is designed to resonate at the frequency of the ultrasonic system. The horn is bonded to the transducer such that excitation of the transducer causes an ultrasonic vibration of the horn. The voltage applied to the transducer can determine the amplitude of the horn, which can affect how well certain materials respond to the bonding. A vibrating reed is sometimes used which is driven by a transducer and horn transverse to the reed, in order to apply a low-amplitude force directly to the part being bonded. In a similar application, an ultrasonic tool can be used to “weld” parts, such as thermoplastic parts, by applying the energy to the parts in order to provide localized heating. In yet another application, an ultrasonic device can be used as a cutting or slicing apparatus, for applications such as surgery and material separation. In a typical ultrasonic cutting device, a “blade” tool element is bonded to the transducer such that the blade moves back and forth in a sawing action at an ultrasonic frequency. While the range of motion is relatively small, the high rate of acceleration does not allow the material being cut to move with, or stick to, the blade portion. Ultrasonic scalpels, for example, are used by surgeons who wish to make an incision without exerting any pressure on the patient. The heat generated by these ultrasonic vibrations can also be useful, as various fabrics can be sealed while cutting, in order to minimize fraying.

These and other ultrasonic applications suffer from many of the same problems as the cleaning applications, however, as it still can be difficult to transfer a sufficient, uniform amount of ultrasonic energy. Further, problems with erosion still exist for any materials vibrated at the ultrasonic frequency, particularly near points at which those materials are bonded to the transducers. It is therefore desirable to develop an improved ultrasonic approach that eliminates these and other problems currently associated with ultrasonic devices and approaches.

### BRIEF DESCRIPTION OF THE DRAWINGS

FIG. 1 is a diagram of an ultrasonic cleaning device of the prior art.

FIG. 2 is a diagram of an ultrasonic tool of the prior art.

FIG. 3 is a diagram of an ultrasonic cleaning device in accordance with one embodiment of the present invention.

FIG. 4 is a diagram of an ultrasonic tool in accordance with one embodiment of the present invention.

FIG. 5 is a photograph showing erosion of stainless steel after 2 hours of operation.

FIG. 6 is a photograph showing no noticeable erosion of silicon carbide after 500 hours of operation.

### DETAILED DESCRIPTION

Ultrasonic power at or near a predetermined frequency, such as in the range of from about 15 kHz to 5 MHz, can be used to provide energy to an object, such as a tool or a tank, to perform a desired task, such as providing for ultrasonic cleaning, bonding, and/or cutting. For many applications, higher frequencies in this range tend to produce more favorable results. While early ultrasonic tools consisted of transducers and tanks or tools made primarily from stainless steel, a ceramic transducer tool, utilizing Advanced Ceramic materials, can provide significant improvements in performance. See for example U.S. Pat. Nos. 5,748,566 and 5,998,908, which are hereby incorporated herein by reference. As used herein, “Advanced Ceramics” is intended to refer generally to ceramic materials having a minute grain size, such as on the order of a few microns or a fraction of a micron, which have a relatively high density with near zero porosity as measured in microns. One such Advanced Material is silicon carbide (SiC). The grain structures in Advanced Ceramics are almost perfectly uniform, allowing ultrasonic signals to propagate evenly in every direction without substantial variations or “hot spots.” Transducerized objects made from Advanced Ceramics can provide for process enhancement due at least in part to the fact that the granular structure of these materials can distribute the ultrasonic energy in a manner similar to that of a tool which itself is a resonator, broadcasting the sound throughout the entirety of the advanced ceramic. Advanced Ceramic materials can offer similar advantages when used to form other parts associated with an ultrasonic tool and/or tank, such as internal fixtures used to support or hold workpieces during treatment, as well as any devices used to connect the fixtures to the tool or tank. Using ultrasonic materials such as piezoelectric crystals or ceramics with these Advanced Ceramics can provide for more efficient ultrasonic processing than could be obtained with previous systems.

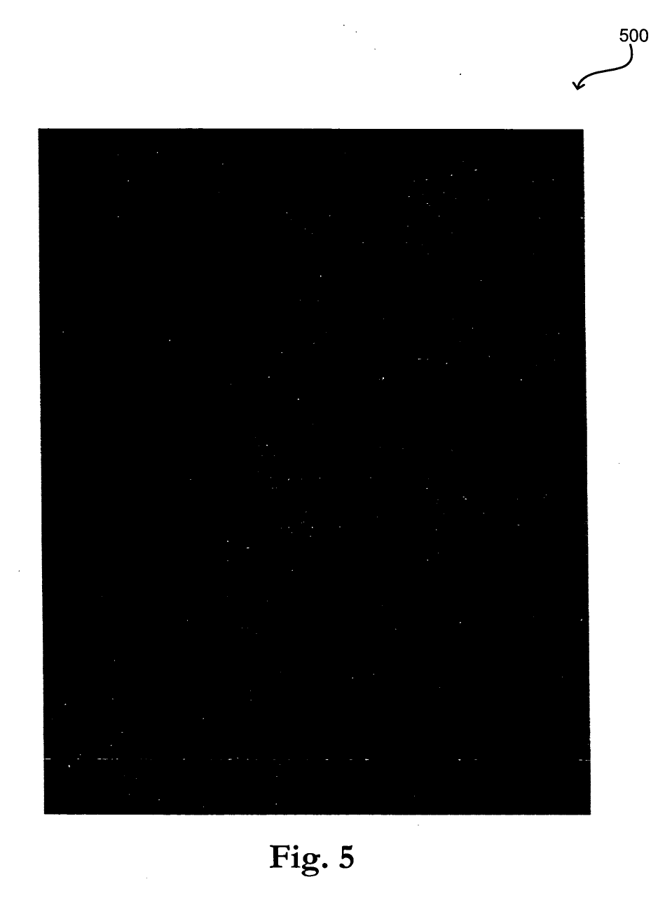

In an ultrasonic system of the prior art in which parts can be ultrasonically cleaned while submerged in a stainless steel tank, for example, ultrasonic transducers are bonded to the tank, using a standard bonding process as known in the art. In other existing systems, the transducers can be bonded to a tool such as a medical slicing device or wire bonding apparatus. The bonding of the transducers tends to restrict the even flow of ultrasonic energy, as the energy tends to propagate primarily through weaker spots in the steel. Experiments have shown that signs of cavitation and erosion 500 begin to appear in the walls of a stainless steel tank within two hours of starting ultrasonic cleaning in the tank, as shown in FIG. 5.

Systems and methods in accordance with various embodiments of the present invention can overcome these and other deficiencies in existing ultrasonic processes and systems. Specifically, enhanced performance can be obtained by forming various elements and/or components of an ultrasonic tool from Advanced Ceramic materials, and attaching the tool directly to the ultrasonics, such that the tool functions as a single, fully-integrated entity. The tool can include any component useful for ultrasonic applications, including components such as a container, tank, vessel, blade, horn, flange, etc., capable of being formed of an Advanced Ceramic material. Piezo ceramics such as PZTs (piezo ceramics of lead zirconate titanate, as known in the art) can be used to provide the ultrasonic energy. These piezo ceramics can be directly attached to the tool (or tank), individually or in sandwich stacks, such that the tool and PZTs can act as a single transducer, or as a unified transducer wherein the transducer can encompass both the piezo ceramics and the tool as a unified object. In such a unibody approach, the ultrasonic elements can be attached and/or stacked directly on the Advanced Ceramic tool using any of a number of approaches known and used in the art, such by as using an appropriate glue, adhesive, or epoxy to attach the ultrasonics directly to the tool. In one embodiment the transducer is attached to the tool using an epoxy polymer adhesive Supreme 10AOHT, which contains a ceramic filler of aluminum oxide and is a heat curing epoxy with high shear strength and high peel strength. The adhesive also is thermally conductive and resistant to severe thermal cycling.

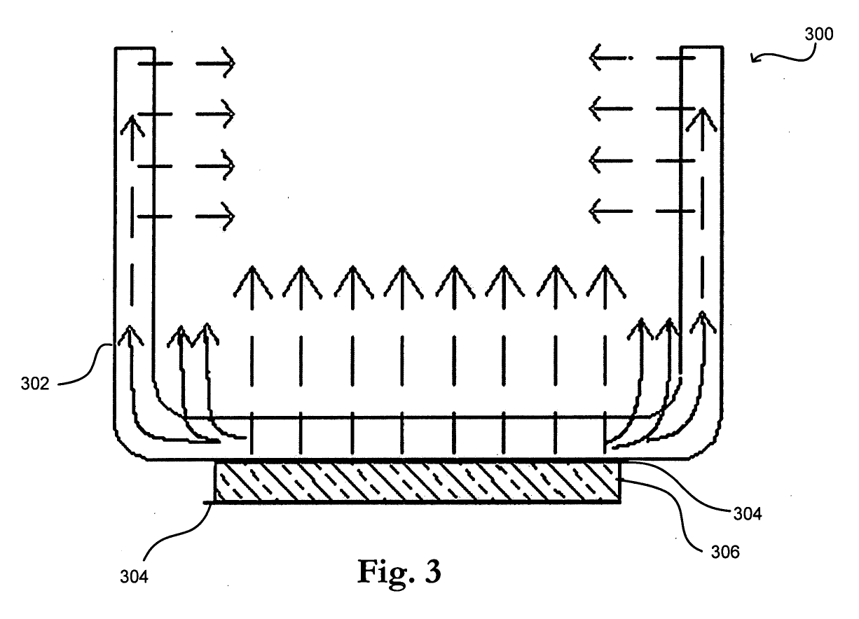

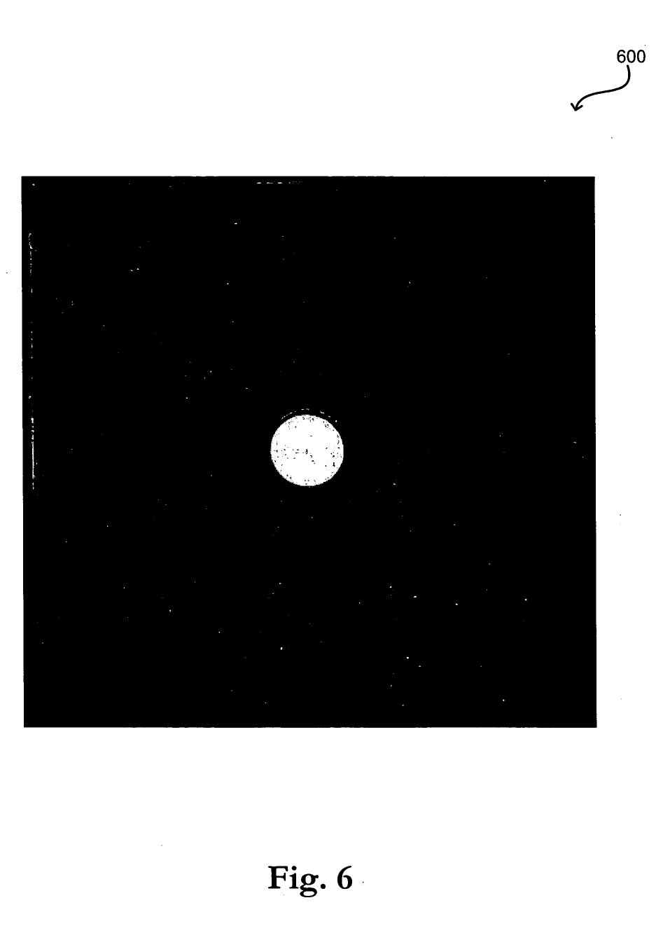

The integration of the ultrasonic elements and the tool can be further enhanced by setting the thickness of the tool to an optimum thickness, such as a half-wavelength multiple of a PZT used to excite the tank, whereby the tool can resonate uniformly with the object(s) being excited. In an embodiment wherein parts can be ultrasonically cleaned while submerged in a tank, such as is shown in the device 300 of FIG. 3, a transducerized tank 302 can be formed from an Advanced Ceramic such as silicon carbide, in accordance with the present invention. Silicon carbide (SiC) is a preferred form of Advanced Ceramic for many applications, and can be formed from a chemical reaction with graphite as known in the art. A silicon carbide tank similar to that of FIG. 3 showed no signs of erosion 600 after 500 hours of ultrasonic operation, as shown in FIG. 6.

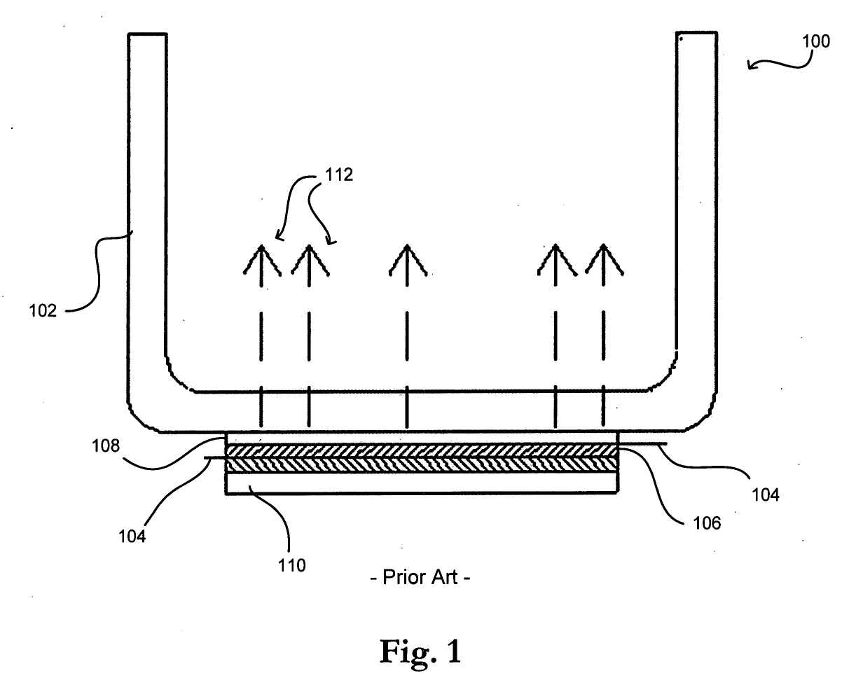

In the Figure, the transducer is shown to be attached directly to the bottom of the tank 302, although this and or other transducers could be attached equally well to other locations and/or walls of the tank. Here, a single PZT 306 element and pair of electrodes 304 make up the transducer. As can be seen from the arrows, the direction of ultrasonic energy propagation is spread much more uniformly throughout the tank than in the existing system shown in FIG. 1. Even in the liquid in the tank, such an approach can provide a variation in transmission of less than 10 percent. In other embodiments, the transducers can be mounted inside an Advanced Ceramic box (not shown), or other immersible as known or used in the art, that is at least partially submerged in the fluid. In another embodiment, an Advanced Ceramic rod with protected transducers mounted on at least one end of the rod can be lowered into a fluid in an Advanced Ceramic tank to provide the ultrasonic energy.

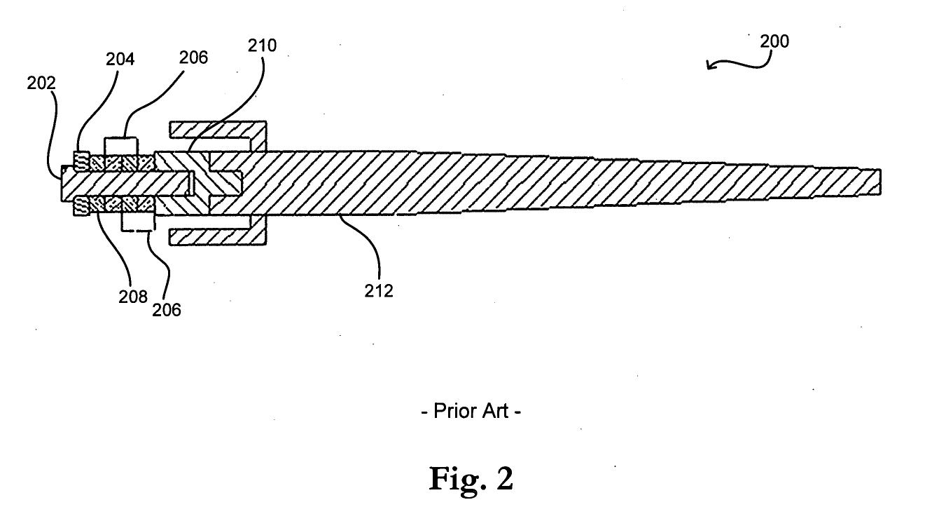

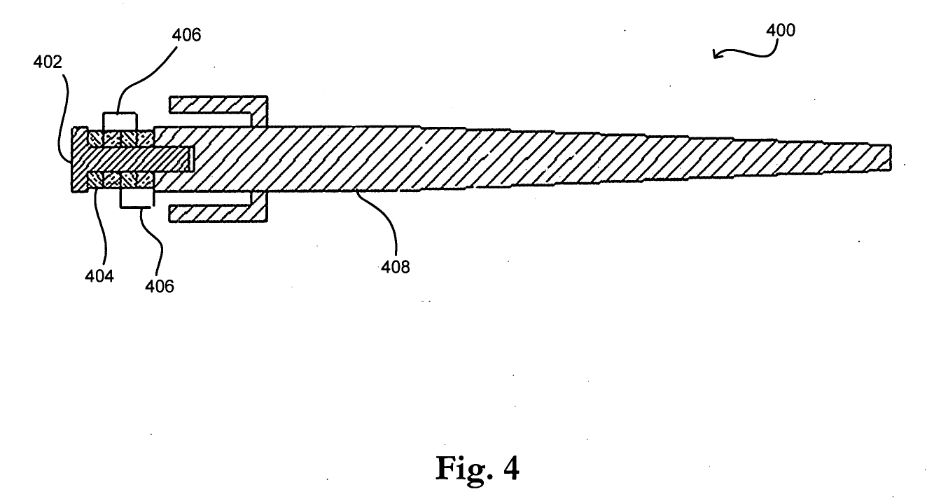

Other ultrasonic devices and applications can benefit from the use of Advanced Ceramic tools directly attached to a piezoelectric assembly, such that the tool and assembly act as a single resonator. For example, FIG. 4 shows an exemplary ultrasonic device 400 in accordance with one embodiment of the present invention. Similar to the prior art device of FIG. 2, a bolt 402 can pass through a ring PZT stack 404, or single PZT element, into an extended tool portion 408. A pair of electrodes 406 is shown for energizing the PZT element(s). The extended tool portion 408 can have a size and shape that is dependent upon the application, such as a blade for a cutting application or a horn for a bonding application, and can be attached direction to the PZT element(s) 404. The extended tool portion can be made of an Advanced Ceramic material, and made of an appropriate thickness, such that the extended tool portion can resonate at the ultrasonic frequency, and the ultrasonics and the tool potion act as a single transducer.

While a stainless steel tank in a cleaning application has been discussed for purposes of illustration for prior art systems, similar problems of erosion and cavitation have been encountered when using other fixtures or tools made of stainless steel or other metals. Advanced Ceramics can be used as fixtures, trays, and various other apparatus used to assist in ultrasonic applications. An Advanced Ceramic apparatus also will resonate in its entirety, as opposed to a metal apparatus. Plastics tend to perform even less favorably than metals. For high-precision applications, such as critical cleaning applications or medical device applications, Advanced Ceramics can offer improved performance in almost every application. In another advantage, Advanced Ceramics can be used in virtually any liquid, including alkalines and most acids that would quickly erode most metals.

A stainless steel tank or tool typically will have strong and weak spots when excited with ultrasonics. Because these weak spots allow for the easy passage of the ultrasonic energy, these spots can erode much more quickly and, subsequently, can cause the tank to fail when liquid from the tank leaks through to the transducers. Advanced Ceramic transducerized tanks and tools made from materials such as silicon carbide show virtually no sign of cavitation erosion. It should be noted, however, that these transducerized objects made from silicon carbide can be more brittle than metal, such that greater care must be taken in order not to damage the transducerized objects.

Transducerized tools (or tanks) made of Advanced Ceramics such as silicon carbide can transmit energy with near-perfect uniformity throughout the tool, such that the tool in effect becomes a resonator as discussed above. Previous systems did not take advantage of this uniformity, as ultrasonic cleaners used stainless steel tanks and tools, quartz tanks, and plastic liners in stainless steel tools, as well as some Pyrex glass containers. Quartz, stainless steel, and plastic lined tanks, as well as other ultrasonic tools, transmit primarily at the point of bonding of the transducer. This direct contact creates a direct transmission of the sound at the point of bonding. In fact, materials such as stainless steel and quartz will begin to reflect the point of transmission as a hot spot or point of erosion. There is virtually no indication of any erosion with a silicon carbide tank having PZTs bonded directly thereto, as the granular composition of silicon carbide uniformly distributes the energy throughout the entire tank. The silicon carbide in effect becomes a transducer when caused to resonate by transducer assemblies connected thereto. The tank then can uniformly blend and distribute ultrasonic energy in the tank or tool. The tank in this case is resonating as a single transducer with near perfect transmission. Pressure readings in all sections of the tank can be the same, regardless of location, whereas the pressure in other tanks is at best about 85% as uniform as an advanced ceramic tank such as Silicon Carbide. Tools are similarly uniform, unlike previous tools such as metal tools which regularly have to be discarded. Fixtures, trays, and other apparatus used to hold parts, or otherwise assist in positioning items being ultrasonically excited, can resonate and uniformly allow the ultrasonic energy to pass through. Stainless steel, on the other hand, only resonates when the frequency of the transducers being used is the same as that of the fixtures, etc., which will not occur for most applications.

It should be recognized that a number of variations of the above-identified embodiments will be obvious to one of ordinary skill in the art in view of the foregoing description. Accordingly, the invention is not to be limited by those specific embodiments and methods of the present invention shown and described herein. Rather, the scope of the invention is to be defined by the following claims and their equivalents.

What is claimed is:

1. An ultrasonic device for generating and transmitting sonic energy, comprising:
a tool consisting of an Advanced Ceramic material; and
an ultrasonic transducer assembly attached directly to the fool, whereby excitation of the transducer assembly causes the tool to resonate at substantially the same ultrasonic frequency as the transducer.

2. An ultrasonic device according to claim 1, wherein:
the Advanced Ceramic material is silicon carbide.

3. An ultrasonic device according to claim 1, wherein:
the ultrasonic assembly includes one of a single PZT element and a sandwich stacked PZT assembly.

4. An ultrasonic device according to claim 1, wherein:
the tool and the ultrasonic transducer act as a unified resonating transducer upon excitation of the transducer assembly.

5. An ultrasonic device according to claim 1, wherein:
ultrasonic waves produced by the ultrasonic transducer assembly propagate substantially uniformly through a granular structure of the Advanced Ceramic tool, without forming hot spots in the granular structure.

6. An ultrasonic device according to claim 1, wherein:
the tool includes one of a blade of an ultrasonic cutting device and a horn of an ultrasonic bonding device.

7. An ultrasonic device according to claim 1, wherein:
a thickness of the tool is a half wavelength multiple of the ultrasonic frequency in order to enhance a resonance capability of the tool upon excitation by the ultrasonic transducer assembly.

8. An ultrasonic cleaning system, comprising:
a tank for holding a liquid and receiving at least one part to be cleaned, the tank consisting of an Advanced Ceramic material; and
an ultrasonic transducer assembly mounted directly to an exterior of the tank, whereby excitation of the ultrasonic transducer assembly causes the tank to resonate at the same frequency as the transducer, thereby transmitting ultrasonic energy to the liquid.

9. An ultrasonic cleaning system as recited in claim 8, further comprising:
a holding fixture mounted in said tank for holding the at least one part to be cleaned, the fixture consisting of an Advanced Ceramic material

10. An ultrasonic cleaning system as recited in claim 8, wherein:
the tank consists of silicon carbide.

11. An ultrasonic cutting device, comprising:
a blade consisting of an Advanced Ceramic material;
a body attached to the blade for positioning the blade; and
an ultrasonic transducer assembly attached directly to the blade, whereby excitation of the transducer assembly causes the blade to resonate at substantially the same ultrasonic frequency as the transducer.

12. An ultrasonic cutting device according to claim 11, wherein:
the Advanced Ceramic material is silicon carbide.

13. An ultrasonic cutting device according to claim 11, wherein:
the ultrasonic assembly includes one of a single PZT element and a sandwich stacked PZT assembly.

14. An ultrasonic wire bonding device, comprising:
a horn consisting of an Advanced Ceramic material;
a body attached to the horn for positioning the horn near a wire to be bonded to a surface; and
an ultrasonic transducer assembly attached directly to the horn, whereby excitation of the transducer assembly causes the horn to resonate at substantially the same ultrasonic frequency as the transducer.

15. A method of ultrasonically cleaning a part, comprising the steps of:
at least partially immersing the part in a cleaning fluid in a tank, the tank consisting of an Advanced Ceramic material; and
activating an ultrasonic transducer assembly attached directly to a surface of the tank, whereby the transducer assembly causes the tank to resonate at substantially the same ultrasonic frequency as the transducer in order to transmit waves of energy to the cleaning fluid.

16. A method according to claim 15, further comprising:
allowing sufficient cavitation of the cleaning fluid, caused by the waves of energy transmitted to the cleaning fluid, whereby contaminants are removed from a surface of the part.

17. A method for transferring ultrasonic energy to a material, comprising the steps of:
attaching an ultrasonic transducer assembly directly to a tool consisting of an Advanced Ceramic material;
activating the ultrasonic transducer assembly, whereby the tool will resonate at substantially the same ultrasonic frequency as the transducer; and
bringing the tool in contact with the material, whereby ultrasonic energy produced by the resonating of the tool is transferred to the material.

18. A method of ultrasonically cutting a material, comprising the steps of:
attaching an ultrasonic transducer assembly directly to a blade of a cutting device, the blade consisting of an Advanced Ceramic material;
activating the ultrasonic transducer assembly, whereby the blade will resonate at substantially the same ultrasonic frequency as the transducer; and
bringing the blade in contact with the material, whereby the resonating of the blade will cut the material without applying substantial pressure to the material.

19. A method of ultrasonically bonding a wire to a material, comprising the steps of:
attaching an ultrasonic transducer assembly directly to a horn of a wire bonding device, the horn consisting of an Advanced Ceramic material;
activating the ultrasonic transducer assembly, whereby the horn will resonate at substantially the same ultrasonic frequency as the transducer; and
bringing the horn in contact with one of the wire and the material, whereby the resonating of the horn bond the wire to the material.
